(19) United States
(12) Patent Application Publication
(10) Pub. No.: US 2009/0268400 A1
(43) Pub. Date: Oct. 29, 2009

(54) PORTABLE ELECTRONIC DEVICE

(75) Inventor: CHAO-JEN CHEN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/430,908

(22) Filed: Apr. 28, 2009

(30) Foreign Application Priority Data
Apr. 28, 2008 (CN) 200810301332.8

(51) Int. Cl. G06F 1/16; H05K 7/00

(52) U.S. Cl. 361/679.55; 361/679.27

(57) ABSTRACT

A portable electronic device includes a main unit and a stand for supporting the main unit. The stand includes a seat rotatablely connected to the main unit and defining a groove; and a rod including a pivoting end which is pivoted on the main unit and a positioning end which is inserted in the groove.

### BACKGROUND

1. Technical Field

The present disclosure relates to electronic devices, and more particularly to a portable electronic device having an adjustable height.

2. Description of Related Art

Portable electronic devices are widely used all over the world, because of their mobility and small size. A laptop is a typical portable electronic device, which usually includes a main unit with a keyboard, and a display unit pivotally connected to the main unit. The display unit is rotatable relative to the main unit to selectively locate in an open position and a closed position. When in the closed position, the display unit typically covers the keyboard of the main unit. When in the open position, the display unit is rotated away the keyboard of the main unit so that the keyboard and a screen provided in the display unit are exposed and viewable. The laptop may be used to listen to music, watch movies, and so on. However, the height of the display unit or the inclined angle of the keyboard may be non-adjustable according to user preference.

Therefore, a need exits for providing a portable electronic device that can conveniently adjust the height of the portable electronic device.

### BRIEF DESCRIPTION OF THE DRAWINGS

FIG. 1 is an isometric view of a portable electronic device in accordance with a first exemplary embodiment.

FIG. 2 is a right elevational view of the portable electronic device of FIG. 1.

### DETAILED DESCRIPTION

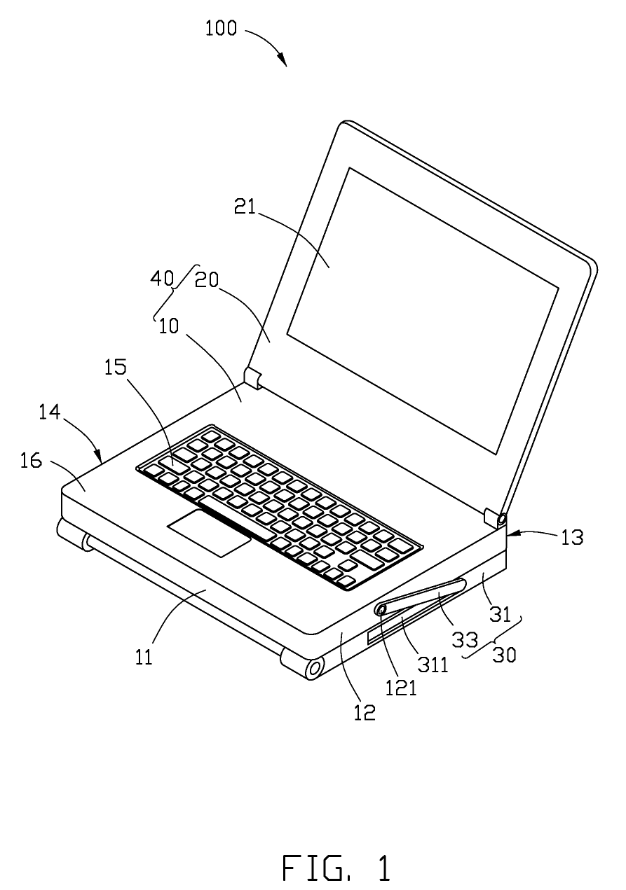

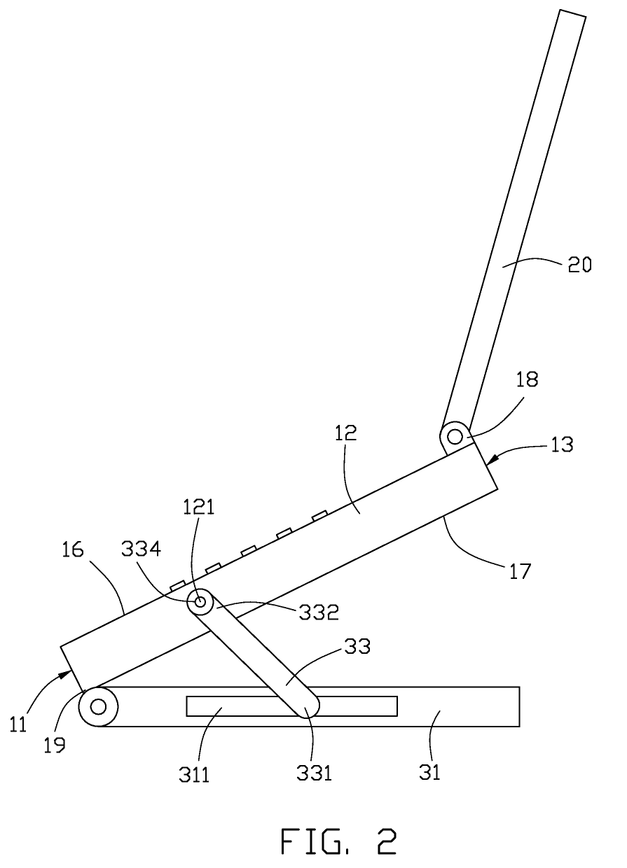

Referring to FIGS. 1 and 2, a portable electronic device in accordance with a first exemplary embodiment is a computer assembly 100. The computer assembly 100 includes a laptop computer 40 and a stand 30 attached to the laptop computer 40 for adjusting the height of the laptop computer 40. The laptop computer 40 includes a main unit 10 and a display unit 20 pivotally attached on the main unit 10. The stand 30 is located at the bottom of the main unit 10. The display unit 20 includes a screen 21 for displaying information of the laptop computer 40.

The main unit 10 includes six walls, e.g. a top wall 16, a bottom wall 17, a front wall 11, a rear wall 13, and two side walls 12 and 14. The display unit 20 is pivotally connected to a first corner 18 of the main unit 10 defined by the top wall 16 and the rear wall 13. The display unit 20 is thus able to be on top of the main unit 10 or rotate to a predetermined angle relative to the main unit 10. A keyboard 15 is disposed at the top wall 16. Two positioning portions 121 are formed on the two side walls 12 and 14 correspondingly. Each of the positioning portions 121 may be a stub protruding from the corresponding side wall 12 or 14.

The stand 30 is used for adjusting the height of the display unit 20 and an inclined angle of the keyboard 15. The stand 30 includes a seat 31 and two rods 33.

The seat 31 may be a flat sheet. The seat 31 is located under the main unit 10 for supporting the main unit 10, and is pivotally connected to a second corner 19 of the main unit 10 defined by the front wall 11 and the bottom wall 17. The seat 31 defines two elongated grooves 311 along a front-rear direction at opposite sides.

The two rods 33 are symmetrically disposed at the two side walls 12 and 14 of the main unit 10 correspondingly. Each rod 33 includes a positioning end 331 which is inserted in the groove 311, and a pivoting end 332 which is pivotally rotatable on the positioning portion 121. The positioning end 331 is slidable along the groove 311 to adjust its location in the groove 311. The pivoting end 332 defines a pivoting hole 334 for receiving the positioning portion 121.

When the stand 30 is in a normal state, the main unit 10 is folded on the seat 31, and the positioning end 331 is located in a first location of the groove 311, such as a first end of the groove 311. When the height of the display unit 20 or the inclined angle of the keyboard 15 needs to be adjusted, the stand 30 can be changed from the normal state to an adjusted state. The positioning end 331 is forced to move from the first location to a second location of the groove 311, such as a middle of the groove 311. The main unit 10 is thus pushed by the rods 33 to rotate relative to the seat 31. A triangular shaped structure is thus obtained cooperatively by the rods 33, the seat 31, and the main unit 10. Therefore, the display unit 20 is adjusted to an appropriate height, and/or the keyboard 15 of the main unit 10 is adjusted to an appropriate inclined angle relative to the seat 31, the positioning end 331 may be fixedly positioned in the groove 311 by friction or abutting force between the positioning end 331 and the groove 311.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A portable electronic device comprising:
a main unit; and
a stand supporting the main unit, the stand comprising:
a seat rotatablely connected to the main unit, and defining a groove; and
a rod connecting with the main unit and the seat, the rod comprising a pivoting end which is pivoted on the main unit, and a positioning end which is movably inserted in the groove.

2. The portable electrical device as claimed in claim 1, wherein the pivoting end of the rod defines a pivoting hole, and the main unit comprises a positioning portion for passing through the pivoting hole.

3. The portable electrical device as claimed in claim 2, wherein the positioning portion is a stub protruding from the main unit.

4. The portable electrical device as claimed in claim 1, wherein the positioning end of the rod is able to move to different locations of the groove.

5. The portable electrical device as claimed in claim 1, wherein the groove is elongated in the front-rear direction of the main unit.

6. The portable electrical device as claimed in claim 1, wherein the main unit includes a top wall, a bottom wall, a front wall, a rear wall, and two side walls, the seat is located under the main unit for supporting the main unit and is pivotally connected to a corner of the main unit which is defined by the front wall and the bottom wall.

7. The portable electrical device as claimed in claim 6, wherein the rod is pivoted on one of the two side walls.

8. The portable electrical device as claimed in claim 6, wherein the pivoting end of the rod defines a pivoting hole, and a positioning portion for passing through the pivoting hole protrudes from one of the two side walls.

9. A portable electronic device comprising:
a laptop computer with a screen; and
a stand for supporting the laptop computer, the stand comprising:
a seat located at the bottom of the laptop computer, and defining a first groove; and
a first rod with one end pivoted on the laptop computer and the other end inserted in the first groove;
wherein the first rod is able to pivot around the laptop computer and slide in the first groove for pushing the laptop computer to rotate relative to the seat, and being positioned in different locations of the first groove for supporting the laptop computer.

10. The portable electrical device as claimed in claim 9, wherein the seat further defines a second groove, and the stand further comprises a second rod with one end pivoted on the laptop computer and the other end received in the second groove.

11. The portable electrical device as claimed in claim 10, wherein the first rod and the second rod are symmetrically disposed at two sides of the laptop computer respectively.

12. The portable electrical device as claimed in claim 10, wherein the first groove and the second groove are elongated in the front-rear direction of the laptop computer.

13. An apparatus, comprising:
a laptop computer comprising a main unit and a display unit, the display unit is pivotally connected to the main unit; and
a rod rotatablely attached to the main unit for supporting the main unit in different inclined positions.

14. The apparatus as claimed in claim 13, further comprising a seat, wherein the rod comprises two ends, one of the two ends is pivoted on the main unit, and the other one of the two ends is movably fastened to the seat.

15. The apparatus as claimed in claim 14, wherein the seat defines a groove, and the other one of the two ends of the rod is slidably inserted in the groove.

16. The apparatus as claimed in claim 14, wherein the main unit comprising two opposite sides, the display unit is rotatablely connected to the main unit at one side of the main unit, and the seat is rotatablely connected to the main unit at the other one side of the main unit.

17. The apparatus as claimed in claim 16, further comprising another rod, the main unit further comprising another two opposite sides interconnected with the two opposite sides, the two rods connected with the main unit at the another two opposite sides.

18. The apparatus as claimed in claim 17, wherein two stubs protrudes from the another two opposite sides, the two rods are rotatable around the two stubs.
